(19) United States
(12) Patent Application Publication
(10) Pub. No.: US 2024/0422893 A1
(43) Pub. Date: Dec. 19, 2024

(54) ELECTRONIC SYSTEM ASSEMBLY

(71) Applicant: Epirus, Inc., Torrance, CA (US)

(72) Inventors: Shawn Warren Merritt, St. George, UT (US); Jeffery Jay Logan, Torrance, CA (US); Oswaldo Medina Garcia, Inglewood, CA (US); Anthony Barry Graback, North Hills, CA (US)

(21) Appl. No.: 18/742,940

(22) Filed: Jun. 13, 2024

Related U.S. Application Data
(60) Provisional application No. 63/472,810, filed on Jun. 13, 2023.

(51) Int. Cl. H05K 1/02; H05K 1/14

(52) U.S. Cl. CPC H05K 1/0204; H05K 1/144; H05K 2201/042

(57) ABSTRACT

An assembly, comprising a first subassembly that includes a first heatsink having a first side and a second side opposite to the first side, a first circuit board mounted to the first side, the first circuit board including a first set of electronic components, a second heatsink having a third side and a fourth side opposite to the third side, the fourth side in contact with the second side, a second circuit board mounted to the third side, the second circuit board including a second set of electronic components, and a first plurality of connecting means securing the first heat sink and the second heat sink together.

### CROSS-REFERENCE TO RELATED APPLICATIONS

This application claims priority to U.S. Provisional application 63/472,810, filed Jun. 13, 2023, titled “Electronic System Assembly,” which is incorporated by reference in its entirety.

### TECHNICAL FIELD

The present disclosure relates, in general, to systems and methods of electronics and, more particularly, to the systems and methods of assembling electronic devices.

### BACKGROUND

Compact devices utilize power-dense circuits that fit within a limited substrate or space in general. Managing heat generated by these power-dense circuits or high-power components on a limited substrate space or within a confined volume may result in significant reliability concerns.

### SUMMARY

In some implementations, the disclosure contemplates systems and methods for configuring power-dense circuits and assemblies. In various implementations, the present disclosure provides a structure supporting multiple high-power components or circuits on both sides of an assembly. The assembly includes a common heat sink to manage the heat dissipation from various high-power components or circuits, resulting in a more compact and efficient system.

In various implementations, the disclosure introduces a technique for cooling high-power components or circuits on both sides of the assembly by integrating substrates with a common heat sink. The common heat sink may include a phase change material for heat absorption or thermal management. In various implementations, the heat sink may include defined cavities, openings, or channels to accommodate the phase change material. In some implementations, the heat sink may employ a combination of cooling techniques, for example, air, water, and/or phase change material, to enhance the overall power efficiency of the electronic system assembly.

In some implementations, the disclosure further provides an electronic system assembly comprising a plurality of subassemblies. Each subassembly of the plurality of subassemblies includes a first circuit assembly on a first side of the subassembly and a second circuit assembly on a second side of the subassembly. A common heat sink is provided on the subassembly that is accessible to the first side and the second side of each substrate for the heat dissipation. The plurality of subassembly are arranged radially about a central support structure and a radome is disposed over a first side of the central support structure.

In various implementations, the radome disclosed includes a ring and a main body. The ring and the main body, when assembled together, may form a semispherical shape. The semispherical shaped radome is disposed over a first side the central support structure.

In various implementations, the plurality of subassemblies are arranged in a lattice structure and the radome is disposed over a first side of the lattice structure.

The systems, methods, modules, and devices of this disclosure each have several innovative aspects, no single one of which is solely responsible for the desirable attributes disclosed herein.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations.

FIG. 1 illustrates a plan view of an example first electronic system assembly according to one or more implementations.

FIG. 2A illustrates a perspective view of an example first electronic assembly according to one or more implementations.

FIG. 2B illustrates a cross-sectional view of the first electronic assembly according to one or more implementations.

FIG. 3A illustrates an exploded view of a first example of an electronic assembly according to one or more implementations.

FIG. 3B illustrates another exploded view of a second example of an electronic assembly cavities according to one or more implementations.

FIG. 4A illustrates a perspective view of an example second electronic system assembly including a plurality of first electronic system assemblies arranged in a radial structure according to one or more implementations.

FIG. 4B illustrates a perspective view of an example third electronic system assembly including a plurality of first electronic system assemblies arranged in a stacked structure according to one or more implementations.

FIG. 4C illustrates a side view of the example third electronic system assembly of FIG. 4B according to one or more implementations.

FIG. 5 illustrates a first exploded view of fourth electronic system assembly according to one or more implementations.

FIG. 6 illustrates a second exploded view of the fourth electronic system assembly according to one or more implementations.

FIG. 7 illustrates a perspective view of the fourth electronic system assembly according to one or more implementations.

FIG. 8 illustrates a cross-sectional view of the fourth electronic system assembly taken across the lines B-B of FIG. 7 according to one or more implementations.

FIG. 9 illustrates an example of a radome structure according to one or more implementations.

FIG. 10 illustrates a perspective view of the fourth electronic system assembly contained in a housing according to one or more implementations.

Like reference numerals refer to corresponding parts throughout the several views of the drawings.

### DETAILED DESCRIPTION

The present disclosure relates to an electronic system comprising a plurality of electronic assemblies on both sides of a substrate. In various implementations, the electronic system comprises a plurality of substrates wherein each substrate comprises electronic assemblies on a first side of the substrate and on a second side of the substrate. The plurality of substrates are arranged in a radial structure, and a radome assembly is disposed over the radial structure. Various implementations of electronic system are further disclosed herein follows.

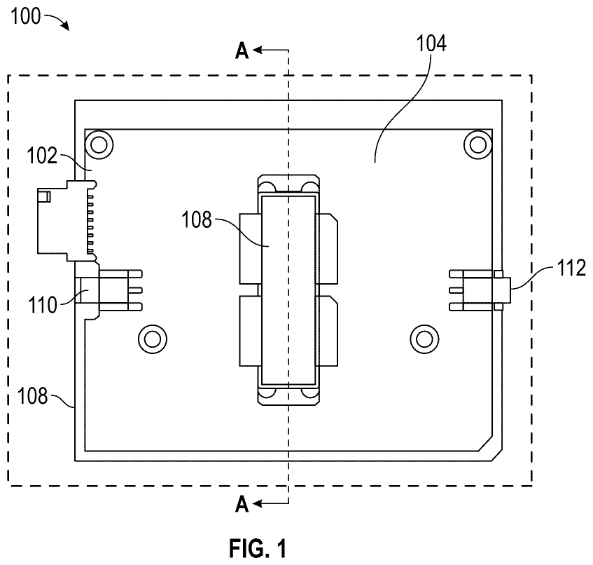

FIG. 1 illustrates a plan view of an electronic system assembly 100 according to one or more implementations. The electronic system assembly 100 includes a heat sink 108 and a substrate 102. The substrate 102 includes a first side (or upper side) 104, which includes a set of electronic devices 106 distributed on the first side 104 of the substrate 104. The plurality of electronic devices 106 may be arranged and interconnected (e.g., via traces and/or planes on or in the substrate 102) to form one or more electronic systems. In some implementations, the one or more electronic systems include a power amplifier configured to amplify an input signal from a first signal level to an output signal at a second signal level. In other implementations, one or more electronic systems include a power converter configured to convert an input with a first type of power characteristic (e.g., voltage, current, amplitude, frequency) to one or more outputs, each having a different type or power characteristic than the first type of power characteristic.

The electronic system of the assembly 100 may include signal conditioners, filters (e.g., EMI filters, LPFs, BPFs, HPFs), transistors, converters, amplifiers, drivers, among others, without departing from the scope of the present disclosure. The substrate 102 also includes a second side (or a lower side) in contact with an upper surface of the heat sink 108. The second side of the substrate 102 may be bonded or attached to the heat sink 108 using one or more methods, such as mechanical means (e.g., fasteners, screws) or thermally conductive adhesive (e.g., solder, epoxy, resin). The electronic system assembly 100 may be designed to receive a first Radio Frequency (RF) signal at an first input 110 and provide a second Radio Frequency (RF) signal at an output 112. The electronic system assembly 100 may include a second input 114 for providing power or other electronic signals to the set of electronic devices 106.

The electronic system assembly 100 and the set of electronic components 106 thereon can be arranged and applied in various applications or electronic circuit configurations beyond what is shown in FIG. 1. For instance, the electronic system assembly 100 may include circuitry for RF applications, power conversion, signal conditioning, amplification, analog circuits, digital circuits, and/or mixed-signal circuits, by way of non-limiting example.

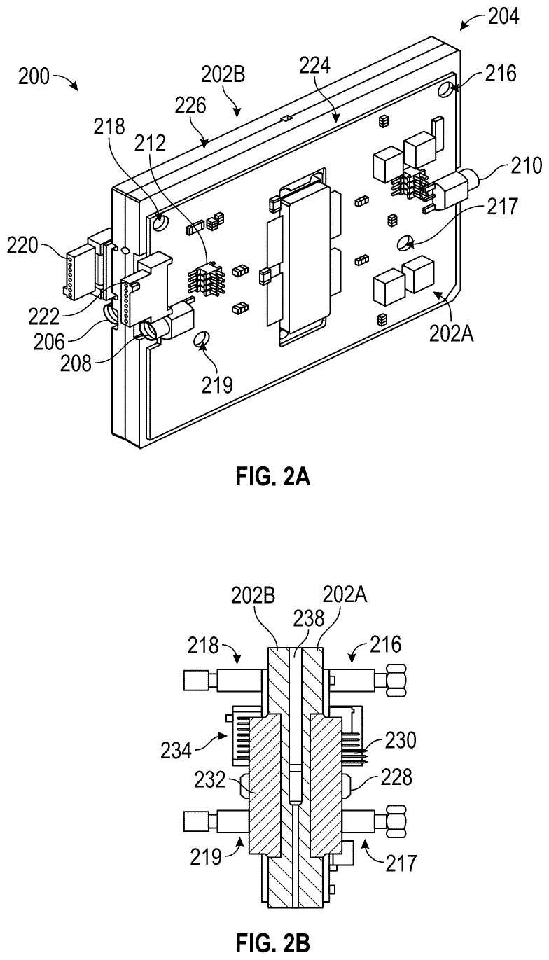

FIG. 2A illustrates a perspective view of an example of an electronic system assembly 200 according to one or more implementations. The electronic system assembly 200 includes a plurality of electronic system assemblies-namely, a first electronic system subassembly 202A and a second electronic system subassembly 202B (not shown). The second subassembly 202B is provided on a surface of the electronic system assembly 200 opposite to the subassembly 202A. The first subassembly 202A and second subassembly 202B (collectively “subassemblies 202”) are similar to the electronic system assembly 100 described in FIG. 1.

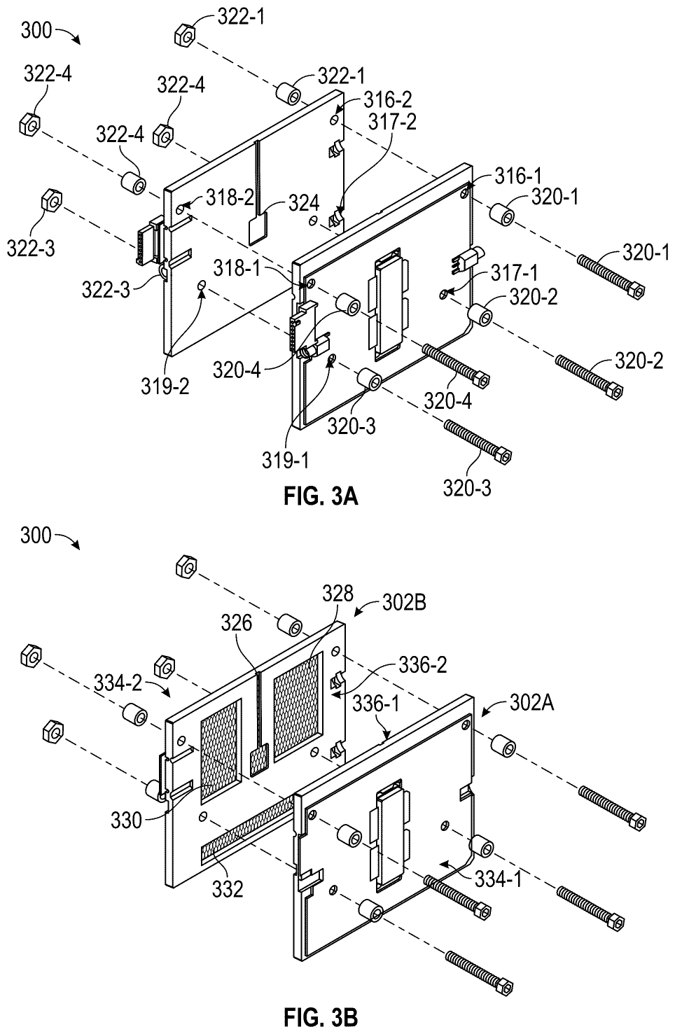

The first subassembly 202A includes a heat sink 224, and the second subassembly 202B includes a heat sink 226. Bottom sides of the heat sinks 224 and 226 are in contact and attached together to form an integrated heat sink 204. For instance, the side of the first and second electronic subassemblies 202A and 202B opposite to a side supporting one or more electronic components may be defined as the back side of heat sinks 224 and 226, respectively. The back side of the heat sink 224 of the first subassembly 202A and the back side of the heat sink 226 of the second subassembly 202B are joined or attached together by connecting means extending through apertures 216a, 217a, 218a, and 219a. The connecting means (see, e.g., FIGS. 2B, 3A, 3B) can include fasteners, screws, adhesive, weld joints, solder joints, pins, or rivets that establish a mechanical connection securing bottom sides of the first subassembly 202A and the second subassembly 202B.

The subassemblies 202A and 202B each include a plurality of connectors for electrical coupling with electronic components or other electronic systems. In some implementations, the first and second subassemblies 202A and 202B respectively include RF signal inputs 206 and 208 to receive first signals at first ends of the subassemblies 202A and 202B. The subassemblies 202A and 202B each include a signal output 210 at second ends of the subassemblies 202A and 202B opposite to the first ends. In some implementations, the first and/or second signals may be RF signals. In some implementations, the first and/or second signals may be DC signals. The second signal may have a different level or amplitude than the first signal.

By way of a non-limiting example, electrical power for enabling the operation of the subassemblies 202A and 202B may be provided via input power connectors 220 and 222. The first sides of the subassemblies 202A and 202B may include a set of connectors or pins 212 to facilitate the electrical connection of a set of electronic components described with respect to FIGS. 3A through 3C and elsewhere herein. In some implementations, the first side of the electronic subassemblies 202 may include without any limitations, circuitry for RF applications, power conversion, signal conditioning, amplification, analog circuits, digital circuits, and/or mixed-signal circuits, by way of non-limiting example.

FIG. 2B, illustrates a cross-sectional view of the electronic assembly 200 taken along the line A-A according to one or more implementations. The first electronic subassembly 202A and the second electronic subassembly 202B are attached to the opposite side via connecting means that extend through connecting means 216, 217, 218, and 219. For instance, the back side of the heat sink of the first electronic subassembly 202A is connected to the back side of the heat sink of the second electronic subassembly 202B via connecting means that extend through connecting means 216, 217, 218, and 219. The first electronic subassembly 202A includes electronic component(s) 228 and connector(s) 230. The second electronic subassembly 202B includes electronic component(s) 232 and connector(s) 234. The electronic assembly 200 may further include a heat sink pipe, opening, channel, or pocket 238 for transferring heat away from the electronic assembly 200 to the external environment.

FIG. 3A illustrates an exploded view of an example of an electronic system assembly 300A including a heat sink according to one or more implementations. The electronic system assembly 300 is similar to the electronic system assemblies 100 and 200 as shown in and described with respect to FIGS. 1 and 2.

The electronic system assembly 300 includes connecting means 320-1, 320-2, 320-3, 320-4, 322-1, 322-2, 322-3, and 322-4 that extend through apertures 316-1, 316-2, 317-1, 317-2, 318-1, 318-2, 319-1, and 319-2 to mechanically attach or join the bottom side of the first subassembly 302A with the bottom side of the second subassembly 302B. For example, the first subassembly 302A includes the connecting holes 316-1, 317-1, 318-1, and 319-1, and the second subassembly 302B includes the connecting holes 316-2, 317-2, 318-2, and 319-2. The connecting holes accommodate connecting means, for example, nuts, screws, bolts, pins, rivets, fasteners, or solder joints, that extend through the apertures 216a, 217a, 218a, and 219a in the subassemblies 302A and 302B. The connecting means, such as nuts and rivets/bolts, are shown as 320-1, 320-2, 320-3, and 320-4 in subassembly 302A, and as 322-1, 322-2, 322-3, and 322-4 in subassembly 302B. In other words, the connecting means, for example, extending through connecting holes 316-1, 317-1, 318-1, and 319-1 from subassembly 302A are shown as nuts and rivets/bolts 320-1, 320-2, 320-3 and 320-4 (collectively referred as, 320). The connecting means 320-1, 320-2, 320-3, 320-4, 322-1, 322-2, 322-3, and/or 322-4 (respectively “connecting means 320” and/or “connecting means 322”) extend through connecting holes 316-2, 317-2, 318-2, and 319-2 between subassembly 302A and subassembly 302B are shown as nuts and rivets/bolts 322-1, 322-2, 3222-3, and 322-4 (collectively referred as, 322).

The bottom or back side of the first subassembly 302A is attached with the second subassembly 302B via the connecting means. In various implementations, the subassemblies 302A and 302B may include opening(s), space(s), or pocket(s) cavities that facilitate thermal cooling. For instance, a heat sink opening may be provided in the bottom side of heat sink 224 and 226 of each subassembly 302A and/or 302B to transfer heat away from the circuit components arranged on the circuit board of the electronic assembly 300. The electronic system subassemblies 302A and/or 302B may include a heat sink opening on the back side thereof. Additionally, each of the top sides of the subassemblies 302A, 302B may include a circuit board that contains circuitry for RF applications, power conversion, signal conditioning, amplification, analog circuits, digital circuits, and/or mixed-signal circuits, by way of non-limiting example. Various other features of the electronic assembly 300 are substantially similar to those described with respect to the circuit board assembly 100 and 200 and elsewhere herein, so further description thereof is omitted for brevity.

FIG. 3B illustrates an exploded view of an example of an electronic system assembly 300B including cavities according to one or more implementations. The electronic system assembly 300B includes features similar to the assembly 200 and/or the assembly 300A, so further description thereof is omitted for brevity.

Each of the subassemblies 302A and 302B includes first sides 334-1 and 334-2 (collectively referred to as “first sides 334”) and second sides 336-1 and 336-2 (collectively referred as “second sides 336”). The first sides 334 of the electronic subassemblies 300 include a circuit board comprising a plurality of electronic devices or circuitry for RF applications, power conversion, signal conditioning, amplification, analog circuits, digital circuits, and/or mixed-signal circuits, by way of non-limiting example. The second sides 336 of the electronic system assemblies 302A and 302B include cavities of various shapes to facilitate direct heat dissipation during the operation of the electronic system assembly 300.

The heat sink 338-1 of the subassembly 302A and the heat sink 338-2 of the subassembly 302B are made of thermally and electrically conductive material. For instance, the subassemblies 302 may include copper or aluminum. The second sides 336 of the subassemblies 302 include cavities 326, 328, 330, and 332 for accommodating air, liquid (e.g., water oil), or phase-changing material to transfer thermal energy from the electronic assembly 300B when in operation. One or more of the cavities 326, 328, 330, and 332 may include a channel extending to an exterior of the assembly 300B.

In various implementations, the openings (or cavities or channels) 326, 328, 330, and 332 may include a phase change material to facilitate transfer of thermal energy. The phase change material enhances heat dissipation within the electronic system assembly 300, facilitating the operation of the electronic assembly 300 within desired operating conditions. The phase change material is a material that maintains a solid state at ambient conditions (e.g., less than ˜38° C., less than ˜49° C.), but begins to transition to a liquid state beyond a certain threshold temperature. During the transition from solid state to liquid state, the phase change material undergoes a change in molecular structure from a crystalline arrangement to an amorphous arrangement. The change in molecular structure correlates to the absorption of a greater amount of heat energy relative to at least some materials that maintain a solid state over the same temperature range (e.g., copper, aluminium). As the phase change material cools, the phase change material transitions from the amorphous molecular arrangement to the crystalline molecular arrangement, thereby reverting from the liquid state back to the solid state. Non-limiting examples of the phase change material include polymeric materials (e.g., Polystyrene-g-PEG6000, polyurethane block copolymers, cellulose-g-PEG), organometallic materials (e.g., C10Mn, C12Cu, C10Zn), organic materials (e.g., polyalcohols, paraffins, fatty acids, esters), and inorganic materials (e.g., salt hydrates).

The circuit boards of the subassemblies 302 are securely mounted on heat sinks, facilitating direct heat dissipation during the operation of the electronic system assembly 300. During operation of the electronic system assembly 300, the phase change material in the heat sink cavities (e.g., 328, 326, 330, 332) plays a role in efficiently managing and dissipating the heat generated by the electronic system assembly 300. As the electronic system assembly 300 generates heat while functioning in any circuit, the phase change material transitions between solid and liquid states. This transition enables the phase change material to absorb heat and store heat energy during the heating phase when the electronic system assembly 300 is active. Subsequently, as the temperature decreases and/or the electronic system assembly 300 becomes less active, the phase change material releases this stored heat and transitions back to a solid state as a result of sufficient cooling. This dynamic cycle of transitioning from solid state to liquid state and vice-versa facilitates improved and consistent operation of electronic system assembly 300 and helps to prevent overheating. In various implementations, a combination of cooling techniques is implemented in the electronic assembly 300. For example, a combination of phase change material and water or air cooling methods can facilitate the cooling operations. The arrangements of heat cavities (326, 328, 330, and 332) are shown in FIG. 3B is not limited to the specifics depicted and can be arranged in various shapes and sizes for a broad range of electronic applications or circuits.

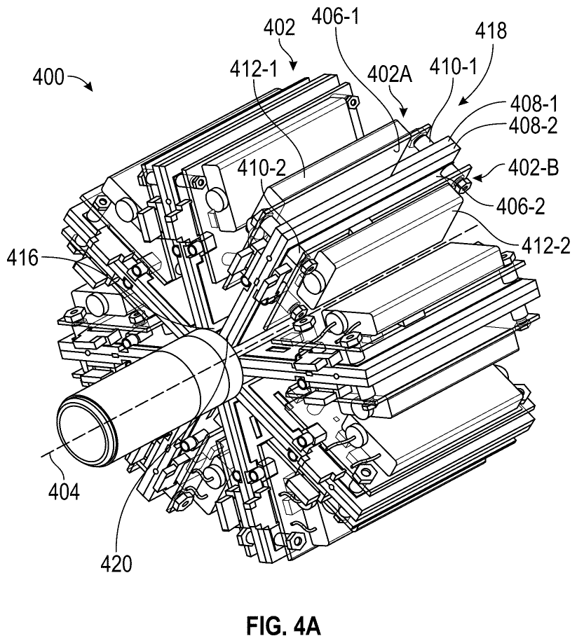

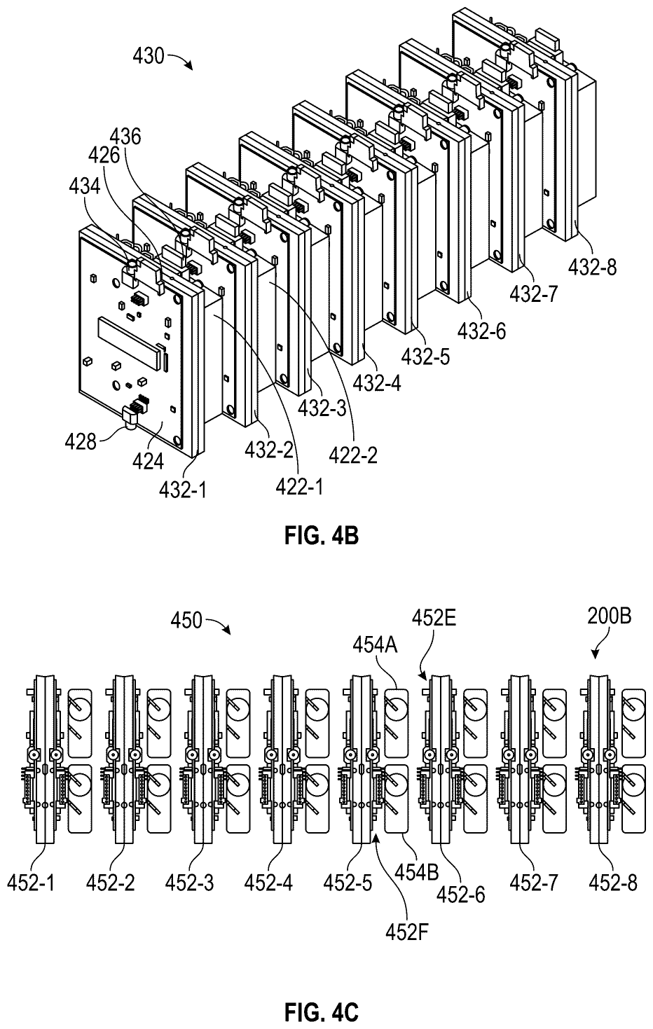

FIG. 4A illustrates a perspective view of an example electronic system assembly 400 in accordance with one or more implementations. The electronic system assembly 400 includes a plurality of electronic system assemblies 402 arranged in a radial structure around a central axis 404. Each of these electronic system assemblies 402 includes a set of electronic system assemblies 402A and 402B substantially similar to those shown and described with respect to FIGS. 2A, 2B, 3A, and/or 3B. Additionally, each set of electronic system assemblies (e.g., 402A and 402B) corresponds to the electronic system assembly 100 as described with respect to FIG. 1.

In various implementations, the electronic system assemblies 402 include a set of electronic components 412-1 and 412-2 electrically coupled to electronic components the subassemblies 402A and 402B, respectively. In some implementations the electronic components 412 may be contained inside a housing. The electronic components 412-1 and 412-2 may be respectively disposed on substrates 406-1 and 410-2and may be interconnected (e.g., via wires, traces, and/or planes) with electronic components of the subassemblies 402 to form an electronic circuit, such as a power amplifier or power converter. In some implementations, the electronic components 412 may be spaced apart from the subassemblies 402A and 402B, respectively, by a plurality of spacers 410-1 and 410-2. The set of electronic components 412 may include a capacitor, an inductor, a resistor, a transistor, a diode, or any other such elements. As a specific non-limiting example, the electronic components may include a supercapacitor configured to support frequent charge and discharge cycles at high current levels in short-duration cycles. Each of the electronic system assemblies 402 may include a set of connectors for connecting to other electronic assemblies, as described elsewhere herein.

Each of the subassemblies 402 is connected to a support structure 416 that extends along a common axis 404. The support structure 416 may be a cylindrical structure formed of metal or plastic, by way of non-limiting example. Each the subassemblies 402 includes a first edge 418 and a second edge 420 opposite to the first edge 418. The second edges 420 of the subassemblies 402 are mechanically connected to the support structure 416. The first sides 418 are spaced apart from each other in a tangential direction around the axis 404. In some implementations, the support structure 416 comprises a single (e.g., monolithic, integrated) body to which the joined subassemblies 402 are mechanically attached.

In some implementations, the support structure 416 is composed of a thermally conductive material (e.g., aluminum) and helps dissipate thermal energy from the electronic system assemblies 400 during operation.

FIG. 4B illustrates a perspective view of an example electronic system assembly 430 according to one or more implementations. The electronic system assembly 430 includes a plurality of the electronic system subassemblies 432-1, 432-2, 432-3, 432-4, 432-5, 432-6, 432-7, 432-8 (collectively referred to as “subassemblies 432”) arranged in a stacked structure. The subassemblies 432 are substantially similar to the subassemblies 202 and/or 302 described with respect to FIGS. 2A through 3B. In some implementations, pairs of the plurality of electronic system assemblies 432 are attached to one or more support structures, which may be a single (or monolithic structure) or a plurality of structures bodies coupled together to form an integrated structure. Each subassembly 432 includes a pair of input ports 434 for receiving input signals. Each subassembly 432 includes a pair of output ports 428 for emitting an output signal. The assembly 430 includes electronic components 422-1 and 422-2 between adjacent subassemblies 432. A first side of the first subassembly 432-1 and/or a second side of the last subassembly 432-8 in the stacked structure of the electronic system assembly 430 may be attached to a fin structure comprised of a metal (e.g., aluminum) or an encasing structure to maintain the thermal or electromagnetic isolation during operation.

FIG. 4C illustrates a side view of the assembly 430 according to one or more implementations. The electronic assembly 430 includes a plurality of the subassemblies 432-1, 432-2, 432-3, 432-4, 432-5, 432-6, 432-7, and 432-8 (collectively referred to as 432), with sets of the electronic components (e.g., 422A, 422B) provided between adjacent ones of the electronic system assemblies (e.g., 422-1, 422-2, 422-3, 432-5, 432-6, 432-7, and 432-8). For instance, a first set of electronic components 422A and a second set of electronic components 422B may be provided between a first side (e.g., 432F) of the electronic system assembly 432-5 and a second side (e.g., 432E) of electronic system assembly 432-6. The plurality of electronic system assemblies (e.g., 432-1, 432-2, 432-3, 432-4, 432-5, 432-6, 432-7, and 432-8) interface with each other using connectors or pins. When connected in a stacked structure, each first set of electronic components (e.g., 422A) and second set of electronic components (e.g., 422B) are electrically coupled to operate as part of the second side (432E) of the electronic assembly 422-6 and first side (422F) of the electronic system assembly 432-5.

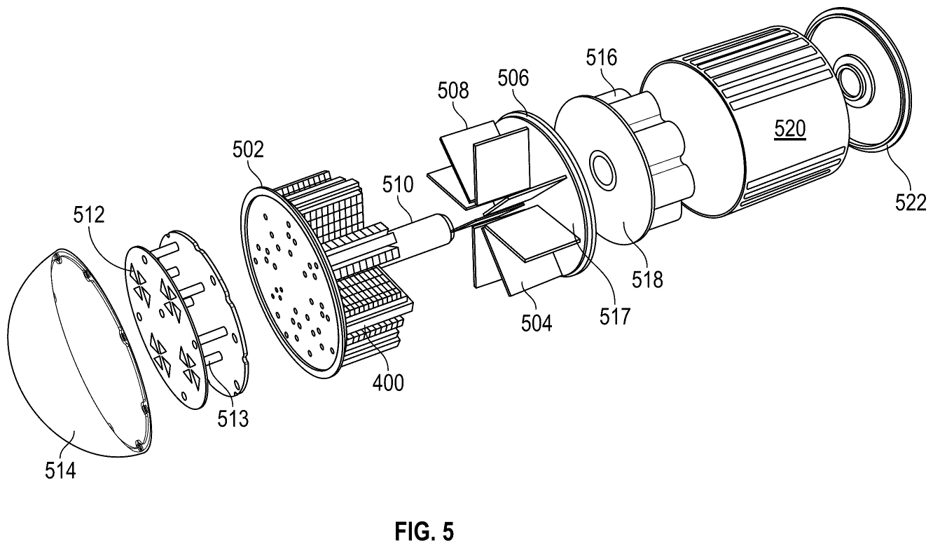

FIG. 5 illustrates an exploded view of an electronic system assembly 500 according to one or more implementations. The assembly 500 includes the electronic system assembly 400 attached to a circular support structure 502, which may include a plurality of connectors or pins provided on a surface thereof. The assembly 500 may include an isolation structure 504 having a circular base 506 and a plurality of fins 508 extending from and arranged radially from the circular base 506. The circular base 506 includes cutouts 517 for conveying input signals to the subassemblies of the assembly 400. When assembled, fins 508 are positioned between adjacent subassemblies of the assembly 400. The plurality of fins 508 provide isolation from electromagnetic interference and/or facilitates the distribution of thermal energy when assembly 500 is in operation. Additionally, assembly 500 may include a support structure 510 extending between a center of the circular structure 502 and a center of the circular base 506. The circular base 506 and/or the circular structure 502 may include apertures and/or connectors sized and shaped to permit access of input and output signals (e.g., see 206, 208, and/or 210 in FIG. 2A) when the circular structure 502, the isolation structure 504, the electronic system assembly 400, and the central support structure 510 are assembled.

The assembly 500 includes an antenna structure 512 comprising a set of antenna elements provided on a support structure 513, which is configured to integrate with the circular structure 502. The support structure 513 is spaced apart from the antenna structure 512 in some implementations. Additionally, the assembly 500 includes a radome 514 that fits over and encloses the antenna structure 512. The antenna elements of the antenna structure 512 may be bowtie antennas, dipole antennas, patch antennas, or aperture antennas, by way of non-limiting example. The assembly 500 may further include a battery pack 516 comprising one or more batteries. In some implementations, the assembly 500 may include connectors to provide power in addition to or instead of the battery pack 516.

The assembly 500 may also include a power management board (PMB) 518 comprising a plurality of electronic components. The PMB 518 may include power electronic components and devices arranged and configured to convert and/or condition power provided by the battery pack 516 and/or an external power source. The PMB 518 may include other power electronics for driving devices of the electronic system assembly 400. In some implementations, PMB 518 includes various electronic components and devices for generating a desired RF signal to be amplified and emitted by the assembly 400. In some implementations, PMB 518 may include various electronic components, driver assembly boards, point of load, and other devices for processing and/or adjusting an RF signal provided by an external source, the RF signal to be amplified and emitted by the assembly 500.

As a particular non-limiting example, the PMB 518 may include an RF signal generator and gate driver circuitry for driving amplifiers of the assemblies 400. For instance, the PMB 518 may include an RF signal generator configured to generate an RF signal between 0.25 GHz and 40 GHz. The RF signal may be passed to a plurality of gate drivers that are configured to amplify the RF signal to a level sufficient to transition amplifiers of the assemblies 400 between a first state (e.g., off state) and a second state (e.g., on state) at a desired frequency.

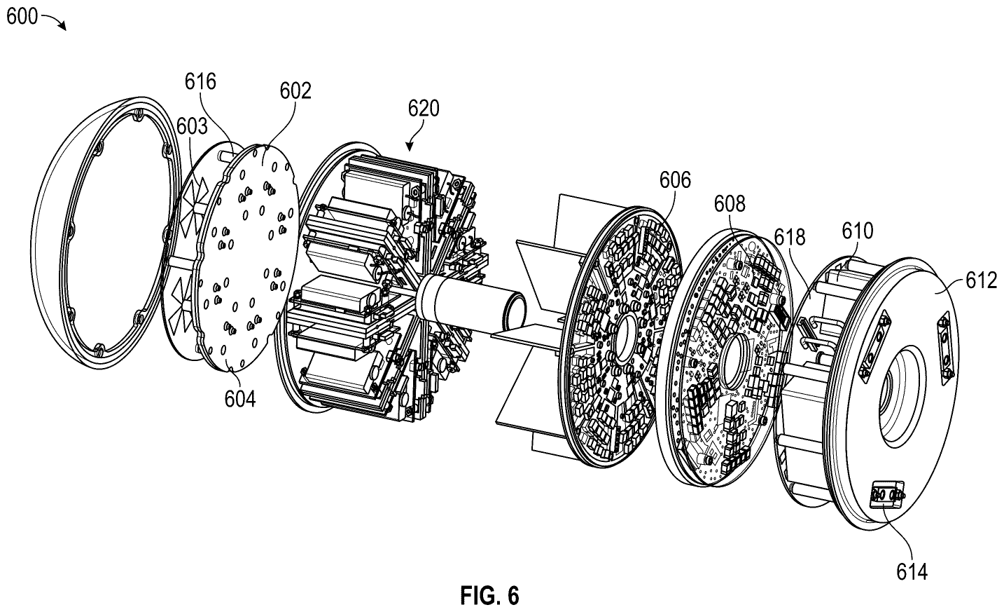

The assembly 500 includes a cylindrical-shaped housing 520. When assembled, housing 520 contains and protects the electronic components and circuits of the assembly 500. For example, when assembled, housing 520 contains system assemblies 400 that fits with the isolation structure 504, the PMB 518, and the battery pack 516. The assembly 500 may include an end cover 522 sized and shaped to engage with the housing 520 and retain the electronic assembly 400, the isolation structure 504, the battery pack 516, and the PMB 518 within the assembly 500. The cover 522 may include one or more apertures or connectors that enable the components of the assembly to receive power and/or signals from one or more external sources. Further elaboration on antenna structure 512, support structure 513, PMB 518, and battery pack 516 is provided with respect to FIGS. 6-8.

FIG. 6 illustrates an exploded view of an assembly 600 according to one or more implementations. The assembly 600 may be substantially similar to the assembly 500 and include features described elsewhere herein. In various implementations, the assembly 600 may include a compact directed energy system.

In various implementations, a compact directed energy system may be a Radio Frequency (RF) system or a directed energy system that is configured to generate directed energy beams in a frequency range between 100 MHZ to 20 Ghz. The assembly 600includes an antenna system 603 coupled to and spaced apart from a ground plane 602 via vertical supports 616. The radome structure 514 when assembled with the cylindrical encasing (or housing) 520 comprising the RF system, the 600 assembly forms the compact directed energy system.

In various implementations, the compact directed energy system may be a radio frequency system that refers to any components utilized for the generation and delivery of RF energy. For example, the RF system can comprise a power system, a point-of-load power distribution system, converters, signal conditioning electronics, high-power amplifiers, sensors, switches, antennas, etc.

In various implementations, the compact directed energy system can generate a directed energy beam in the form of an electromagnetic pulse (EMP) such that the generated RF can be delivered over a substantial portion of a sphere (i.e., 4x steradians) surrounding the antenna(s). The delivered RF energy (either as a beam or as an EMP) can be delivered in a single burst or in multiple bursts, such as part of a pulse train.

The RF system includes a power system comprising a battery system that provides power to multiple loads (e.g., point of load power distribution system 608). In various implementations, the power system can include power converters configured to receive DC power from a common power source. In some implementations, for example, the power system can include an AC power supply. As described further herein, the power converters can be configured to provide DC power to the corresponding point of load power distribution system (or power distribution system) 608. In some implementations, a power management board (PMB) 618 may be configured to interface with a battery system 610. The PMB 618 can distribute power to the point of load power distribution unit (POL PDU) 608. In some implementations, POL PDU 608 may include a voltage regulator, digital to analog converter (DAC), analog to digital converter (ADC), current sensors, bias controller, etc.

The power management board 618 conveys the DC voltage from the battery system 610 to the POL PDU 608. In various implementations, one or more current sensors can sense various characteristics of the received voltage from the battery system 610 and control the bias power using a power controller. The sensed characteristics can include, for example, an input signal power, an output signal power, a gain, a current, a voltage, a temperature, a resistance, a capacitance, or an inductance. In various implementations, the POL PDU 608 can include current limiters or other current sensors that can be configured to shut down the voltage supply if the voltage (or current) exceeds any threshold value. In various other implementations, POL PDU 608 configured to receive power from the power source and convert the received power to voltages and currents that are required by the devices (or load) to which it is connected.

The POL PDU 608 is interfaced using a serial peripheral interface (SPI) or connectors with the driver amplifier board (DAB) 606. The voltage regulator regulates the input voltage from the POL PDU 608 and provides the regulated power to the DAB 606. For example, a voltage regulator may control a 65V supply voltage to a low voltage 55 V and provide the 55V power to the DAB 606. As another example, the voltage regulator may control the low voltage 55 V to high voltage 65 V and provide the high power to DAB 606. In some implementations, the DAB 606 comprises high electron mobility transistors (HEMT)/field effect transistor (FET) amplifying devices, driver amplifiers, and current sensors to sense the current drawn by the HEMT/FET amplifying devices. The DAB 606 receives the regulated voltage (or current) from the POL PDU 608 and amplify the received input to a higher power level of RF signals. The amplified RF signals from the DAB 606 is transmitted to electronic system assembly 620 that comprises a plurality of high-power amplifiers (HPAs). The electronic system assembly 620 discussed with respect to FIGS. 1-5 and elsewhere herein. In various implementations the electronic system assembly 620 or DAB 606 can comprise a RF system on chip (RFSoC), direct digital synthesizer (DDS), and RF system on module (RFSOM) to generate pulsed wave or continuous wave signals in variable frequencies as an output. In various implementations, one or more parameters of the generated RF waveform (e.g., frequency, power, pulse width, duty cycle, chirp, modulation) can be controlled by an external source, such as by a user input via an external controller or by an external control system.

The electronic system assembly 620 generates a high-power RF beam that is directed to antenna system 603. The antenna system 603 can comprise a single antenna or an array of antennas. The antenna system 603 is configured to radiate the electromagnetic (EM) radiations generated by the electronic system assembly 620. In various implementations, the antenna system 603 can comprise a loop antenna, a horn antenna, a dipole antenna, a helical antenna, a dish antenna, a parabolic antenna, a monopole antenna, a rod antenna, an electronically steerable antenna array or other types of antennae.

The assembly 600 can be configured to transmit energy in different frequency bands, for example, in a low frequency range (3-300 KHz), a high frequency range (300 KHz-30 MHz), a very high frequency range (30-300 MHz), an ultra-high frequency range (300 MHz-3 GHz), a super high frequency range (3-40 GHz), or a mega high frequency range (40-100 GHz). The frequency of the EM radiation emitted from assembly 600 can be in one or more of frequency bands, including the SHF band, the UHF band, the L band, the S band, the Ka band and/or the Ku band. Additionally, the size and shape of the antenna system 603 can vary depending on a variety of factors including but not limited to the desired radiated power and the desired range.

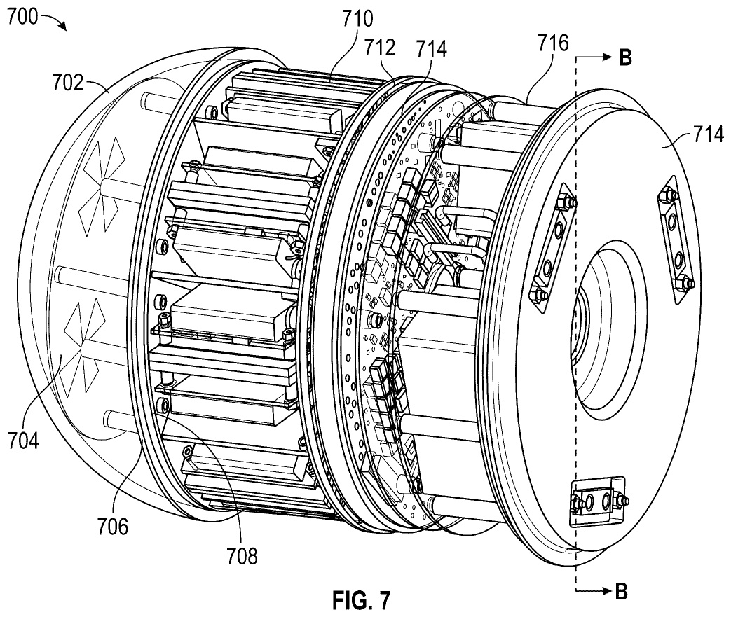

FIG. 7 illustrates an assembled view of an electronic system assembly 700 according to one or more implementations. More particularly, the assembly 700 corresponds to the assembly 500 and/or 600 described herein. The assembly 700 includes a radome structure 702 that houses an antenna system 704 and a ground plane 706. A second side 708 of the ground plane 706 is electrically and mechanically coupled to a first side of electronic system assembly 710 via solder or rivets or screws or conductive paste or electrically conductive epoxy, by way of non-limiting example. A second side of the electronic system assembly 710 is connected to a driver amplifier board (DAB) 712 and POL PDU 714. The POL PDU 714 is configured to receive input power from the power system 716. The power system 716 includes one or more batteries and a back plate 718 electrically and mechanically connected via connectors, screws, rivets, etc.

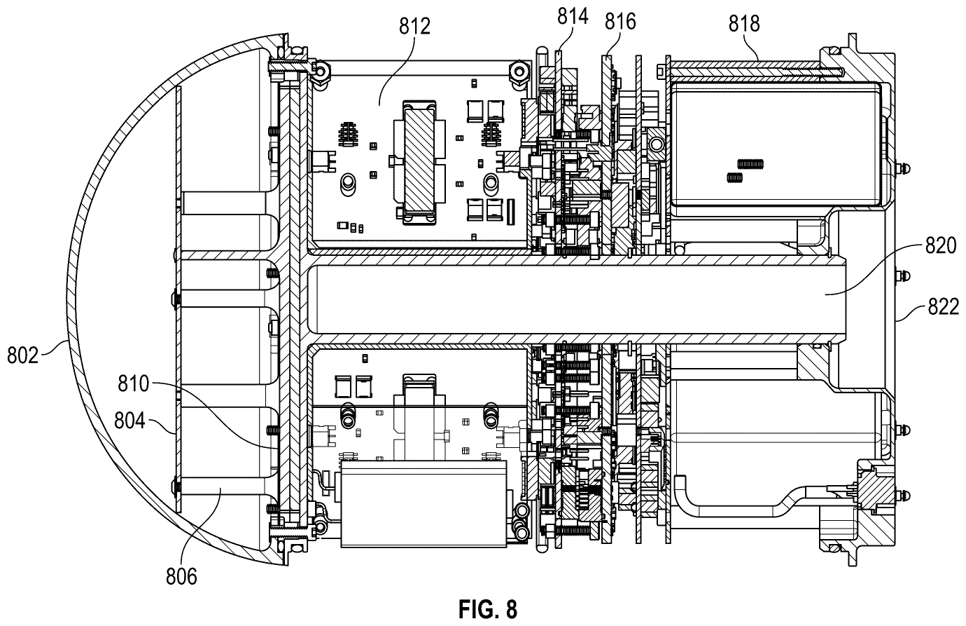

FIG. 8 illustrates a cross-sectional view of the assembled electronic system assembly B-B of FIG. 7, according to one or more implementations. More particularly, assembly 800 corresponds to the assembly 500, 600 and/or 700 described herein. The assembly 800 shows a cross-sectional view of various components, including radome structure 802, antenna system 804, connectors/spacers 806, and ground plane 810 of the antenna system 804. The electronic system assemblies 812-1 and 812-2 (collectively referred to as 812), DAB 814, POL PDU 816, and power system 818 are centrally connected to support structure 820 and are covered by end plate cover 822.

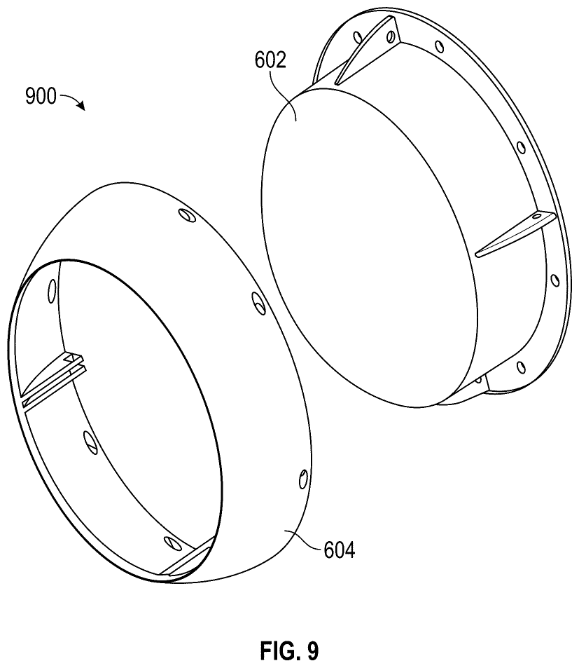

FIG. 9 illustrates an example of a radome structure 900 according to one or more implementations. The radome structure 900 includes a main body 902 and a ring 904. The main body 902, when assembled with ring 904, the assembly forms a semispherical shape. Radome 900 fits over and encloses an antenna system, as discussed with respect to FIGS. 5-8, and elsewhere herein.

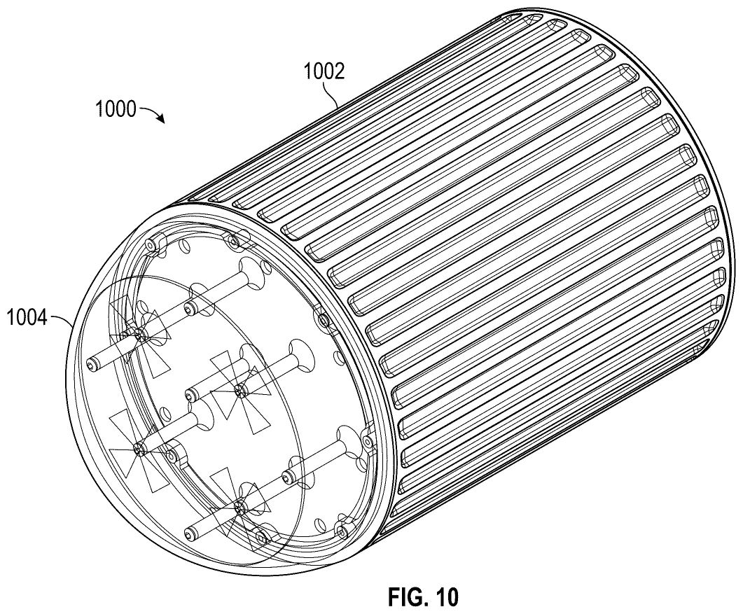

FIG. 10 illustrates a perspective view of the assembled assembly 1000 according to one or more implementations. More particularly, FIG. 10 depicts the embodiment of FIGS. 5-8 but assembled, illustrating the compact design of the disclosed directed energy system assembly. The assembly 1000 illustrates a cylindrical body 1002 and radome structure 1004. The radome structure 1004 fits over and encloses antennae system as discussed with respect to FIGS. 5-8, and elsewhere herein. When assembled, the radome structure 1004 and cylindrical body 1002, the configuration provide a compact directed energy system. The compact energy system can comprise an RF system configured to provide a directed energy beam, as discussed with respect to FIGS. 5-8, and elsewhere herein. In various implementations, the compact directed energy system can be configured as a phased array system comprising an RF signal/waveform generator, high-power amplifiers configured to amplify the generated RF signal, and one or more antennae systems to radiate the amplified RF signal as a directed energy beam.

### Other Variations

Features, materials, characteristics, or groups described in conjunction with a particular aspect, embodiment, or example are to be understood to be applicable to any other aspect, embodiment or example described herein unless incompatible therewith. All the features disclosed in this specification (including any accompanying claims, abstract and drawings), and/or all the steps of any method or process so disclosed, may be combined in any combination, except combinations where at least some of such features and/or steps are mutually exclusive. The protection is not restricted to the details of any foregoing implementations. The protection extends to any novel one, or any novel combination, of the features disclosed in this specification (including any accompanying claims, abstract and drawings), or to any novel one, or any novel combination, of the steps of any method or process so disclosed.

While certain implementations have been described, these implementations have been presented by way of example only and are not intended to limit the scope of protection. Indeed, the novel methods and systems described herein may be embodied in a variety of other forms. Furthermore, various omissions, substitutions, and changes in the form of the methods and systems described herein may be made. Those skilled in the art will appreciate that in some implementations, the actual steps taken in the processes disclosed and/or illustrated may differ from those shown in the figures. Depending on the embodiment, certain of the steps described above may be removed, others may be added. For example, the actual steps and/or order of steps taken in the disclosed processes may differ from those described and/or shown in the figure. Depending on the embodiment, certain of the steps described above may be removed, others may be added. For instance, the various components illustrated in the figures and/or described may be implemented as software and/or firmware on a processor, controller, ASIC, FPGA, and/or dedicated hardware. Furthermore, the features and attributes of the specific implementations disclosed above may be combined in different ways to form additional implementations, all of which fall within the scope of the present disclosure.

In some cases, there is provided a non-transitory computer readable medium storing instructions, which when executed by at least one computing or processing device, cause performing any of the methods as generally shown or described herein and equivalents thereof.

Any of the memory components described herein can include volatile memory, such random-access memory (RAM), dynamic random access memory (DRAM), synchronous dynamic random access memory (SDRAM), double data rate (DDR) memory, static random access memory (SRAM), other volatile memory, or any combination thereof. Any of the memory components described herein can include non-volatile memory, such as magnetic storage, flash integrated circuits, read only memory (ROM), Chalcogenide random access memory (C-RAM), Phase Change Memory (PC-RAM or PRAM), Programmable Metallization Cell RAM (PMC-RAM or PMCm), Ovonic Unified Memory (OUM), Resistance RAM (RRAM), NAND memory (e.g., single-level cell (SLC) memory, multi-level cell (MLC) memory, or any combination thereof), NOR memory, EEPROM, Ferroelectric Memory (FeRAM), Magnetoresistive RAM (MRAM), other discrete NVM (non-volatile memory) chips, or any combination thereof.

Any user interface screens illustrated and described herein can include additional and/or alternative components. These components can include menus, lists, buttons, text boxes, labels, radio buttons, scroll bars, sliders, checkboxes, combo boxes, status bars, dialog boxes, windows, and the like. User interface screens can include additional and/or alternative information. Components can be arranged, grouped, displayed in any suitable order.

Conditional language used herein, such as, among others, “can,” “could,” “might,” “may,” “e.g.,” and the like, unless specifically stated otherwise, or otherwise understood within the context as used, is generally intended to convey that certain implementations include, while other implementations do not include, certain features, elements and/or steps. Thus, such conditional language is not generally intended to imply that features, elements and/or steps are in any way required for one or more implementations or that one or more implementations necessarily include logic for deciding, with or without other input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Disjunctive language such as the phrase “at least one of X, Y, Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain implementations require at least one of X, at least one of Y, or at least one of Z to each be present.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, or within less than 0.01% of the stated amount.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations.

The foregoing description, for purposes of explanation, used specific nomenclature to provide a thorough understanding of the disclosure. However, it will be apparent to one skilled in the art that specific details are not required in order to practice the disclosed implementations. Thus, the foregoing descriptions of specific implementations are presented for purposes of illustration and description. They are not intended to be exhaustive or to limit the disclosure to the precise forms disclosed; obviously, many modifications and variations are possible in view of the above teachings. The implementations were chosen and described in order to best explain the principles of the disclosure and its practical applications, they thereby enable others skilled in the art to best utilize the disclosure and various implementations with various modifications as are suited to the particular use contemplated. It is intended that the claims as presented herein or as presented in the future and their equivalents define the scope of the protection.

1. An assembly, comprising:
a first subassembly including:
a first heat sink having a first side and a second side opposite to the first side;
a first circuit board mounted to the first side, the first circuit board including a first set of electronic components;
a second heat sink having a third side and a fourth side opposite to the third side, the fourth side in contact with the second side;
a second circuit board mounted to the third side, the second circuit board including a second set of electronic components; and
a first plurality of connecting means securing the first heat sink and the second heat sink together.

2. The assembly of claim 1, the first heat sink having a first recess in the second side and the second heat sink having a second recess in the fourth side, the first recess and the second recess defining a first cavity in the first subassembly.

3. The assembly of claim 2, further comprising a phase change material in the first cavity.

4. The assembly of claim 2, wherein the first heat sink has a third recess extending from the first recess to a first edge of the first heat sink and the second heat sink has a fourth recess extending from the second recess to a second edge of the second heat sink, the first recess and the second recess defining a first channel in the first subassembly.
